(19) United States
(12) Patent Application Publication
(10) Pub. No.: US 2017/0117145 A1
(43) Pub. Date: Apr. 27, 2017

(54) BORON NITRIDE FILM FORMING METHOD AND SEMICONDUCTOR DEVICE MANUFACTURING METHOD

(71) Applicant: TOKYO ELECTRON LIMITED, Tokyo (JP)

(72) Inventor: Takahiro MIYAHARA, Nirasaki City (JP)

(21) Appl. No.: 15/296,195

(22) Filed: Oct. 18, 2016

(30) Foreign Application Priority Data
Oct. 26, 2015 (JP) 2015-209646

(51) Int. Cl. H01L 21/02; C23C 16/34; C23C 16/455; H01L 21/3105

(52) U.S. Cl. CPC H01L 21/02337; H01L 21/02112; H01L 21/02271; H01L 21/0228; H01L 21/31051; H01L 21/0234; H01L 21/02362; H01L 21/0217; C23C 16/342; C23C 16/345; C23C 16/45527; H01L 21/28202

(57) ABSTRACT

There is provided a boron nitride film forming method for forming a boron nitride film on a target substrate, including: a first operation of introducing a boron-containing gas and a nitriding gas into a process vessel which accommodates the substrate, and depositing an incompletely-nitrided and boron-rich nitride film on the substrate by CVD or ALD; and a second operation of introducing a nitriding gas into the process vessel and subjecting the boron-rich nitride film to a nitriding process, wherein the first operation and the second operation are performed at least one.

### CROSS-REFERENCE TO RELATED APPLICATION

This application claims the benefit of Japanese Patent Application No. 2015-209646, filed on Oct. 26, 2015, in the Japan Patent Office, the disclosure of which is incorporated herein in its entirety by reference.

### TECHNICAL FIELD

The present disclosure relates to a boron nitride film forming method and a semiconductor device manufacturing method.

### BACKGROUND

In a semiconductor device, a silicon nitride film (SiN film) or a silicon carbonitride film (SiCN film) has been conventionally used as an insulation film for insulating the periphery of a gate of a transistor or a wiring structure,

However, semiconductor devices are becoming smaller to improve performance of the device. This requires an insulation film having a dielectric constant lower than that of a silicon nitride film (SiN film) or a silicon carhonitride film (SiCN film). That is to say, if a dielectric constant of an insulation film is high, a parasitic capacitance increases along with the miniaturization of a semiconductor device. This may cause a signal delay or other problems. Thus, there is a need for an insulation film having a dielectric constant lower than that of a silicon nitride film (SiN film) or a silicon carhonitride film (SiCN film) whose dielectric constant is about 7. In addition, a superior insulation property is needed in an insulation film in order to reduce a leakage current.

A boron nitride film has been proposed as an insulation film having a low dielectric constant and a reduced leakage current.

The boron nitride film is formed by chemical vapor deposition (CVD) or atomic layer deposition (ALD). If a film is sufficiently nitrided in order to secure an insulation property, the morphology of a film surface deteriorates. On the other hand, when one wishes to improve the morphology, it is necessary to perform a film formation process at a low temperature. In this case, a leakage current increases, which makes it difficult to secure a sufficient insulation property.

### SUMMARY

Some embodiments of the present disclosure provide a boron nitride film forming method capable of achieving both good electrical properties, such as a low dielectric constant and a high insulation property, and a good surface morphology, and a semiconductor device manufacturing method using the same.

According to one embodiment of the present disclosure, there is provided a boron nitride film forming method for forming a boron nitride film on a target substrate, including: a first operation of introducing a boron-containing gas and a nitriding gas into a process vessel which accommodates the substrate, and depositing an incompletely-nitrided and boron-rich nitride film on the substrate by CVD or ALD; and a second operation of introducing a nitriding gas into the process vessel and subjecting the boron-rich nitride film to a nitriding process, wherein the first operation and the second operation are performed at least one.

According to another embodiment of the present disclosure, there is provided a boron nitride film forming method for forming a boron nitride film on a target substrate, including: a first operation of introducing a boron-containing gas and a nitriding gas into a process vessel which accommodates the substrate, while keeping a temperature of the substrate at 250 to 400 degrees C., and depositing a boron-rich nitride film on the substrate by CVD or ALD; and a second operation of introducing a nitriding gas into the process vessel and subjecting the boron-rich nitride film to a nitriding process, wherein the first operation and the second operation are performed at least one.

According to yet another embodiment of the present disclosure, there is provided a A semiconductor device manufacturing method, including: forming a boron nitride film on a substrate by one of the aforementioned methods; and forming an insulation film as a cap layer which suppresses moisture absorption of the boron nitride film on the boron nitride film

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart for explaining a film forming method according to one embodiment of the present disclosure.

FIG. 2 is a timing chart illustrating a specific sequence example in which the boron nitride film forming method according to one embodiment of the present disclosure is implemented using an annealing process as a nitriding process.

FIG. 3 is a timing chart illustrating a specific sequence example in which the boron nitride film forming method according to one embodiment of the present disclosure is implemented using a plasma process as a nitriding process.

FIG. 4 is a vertical sectional view schematically illustrating a first example of a film forming apparatus for implementing the boron nitride film forming method according to one embodiment of the present disclosure.

FIG. 5 is a horizontal sectional view schematically illustrating the first example of the film forming apparatus for implementing the boron nitride film forming method according to one embodiment of the present disclosure.

FIG. 6 is a horizontal sectional view schematically illustrating a second example of a film forming apparatus for implementing the boron nitride film forming method according to one embodiment of the present disclosure.

FIGS. 7A and 7B are views illustrating compositions and bond ratios of samples (samples 1 and 3) before and after nitriding annealing when film formation is performed at 550 degrees C. in experimental example 1.

FIGS. 8A and 8B are views illustrating compositions and bond ratios of samples (samples 2 and 4) before and after annealing when film formation is performed at 300 degrees C. in experimental example 1.

FIG. 9 is a schematic diagram illustrating a structure of a TEG sample used in experimental example 2.

FIG. 10 is a view illustrating the relationship between the electric field strength and the leakage current when the electric field strength is changed and the leakage current is measured immediately after and one week after preparation of TEG samples prepared in experimental example 1.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Film Forming Method>

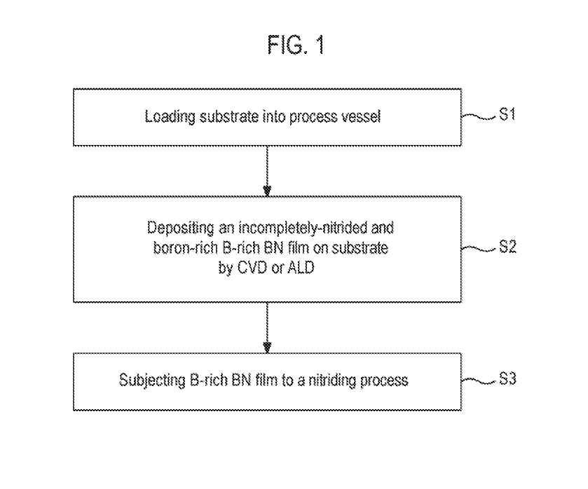

FIG. 1 is a flowchart for explaining a film forming method according to one embodiment of the present disclosure.

In this embodiment, a target substrate is initially loaded into a process vessel (step S1). The target substrate is not particularly limited and may be, for example, a semiconductor substrate (semiconductor wafer), typically a silicon substrate (silicon wafer).

Subsequently, in a state in which an internal temperature of the process vessel is set at a low temperature, a boron-rich boron nitride film which remains in a boron rich state due to an incomplete nitridation (hereinafter referred to as “B-rich BN film”) is deposited on the substrate by CVD in which a boron-containing gas and a nitriding gas are simultaneously introduced into the process vessel or ALD in which a boron-containing gas and a nitriding gas are alternately introduced into the process vessel (step S2).

Then, the nitriding gas is supplied into the process vessel, whereby the B-rich BN film is subjected to a nitriding process (step S3). Thus, the boron contained in the B-rich BN film is nitrided, whereby the B-rich BN film becomes an additionally-nitrided boron nitride film (BN film).

A BN film having a predetermined film thickness is obtained by repeating steps 2 and 3 one or multiple times. The BN film thus obtained has both good electrical properties and a good surface morphology.

In the related art, when a BN film is formed by CVD or ALD using a B₂H₆ gas and an NH₃ gas, it was deemed important that film formation is performed at a relatively high temperature of about 500 to 600 degrees C. in order to obtain a sufficiently-nitrided film having good electrical properties. However, in this case, there was a problem in that the film surface morphology deteriorates.

In contrast, a B-rich BN film formed at a low temperature is insufficiently nitrided. Thus, the B-rich BN film is poor in electrical properties but is good in surface morphology. It was newly found that, by subjecting the B-rich BN film to a nitriding process, it becomes possible to improve electrical properties (e.g., a k value and an insulation property) while maintaining a good surface morphology.

Accordingly, in this embodiment, step S2 of forming an incompletely-nitrided B-rich BN film and step S3 of performing a nitriding process with respect to the B-rich BN film are performed once or multiple times, thereby obtaining a BN film having a predetermined film thickness, in which good electrical properties and a good surface morphology are made compatible.

It is desirable that the BN film thus obtained is nitrided so as to become a film in which boron and nitrogen have a composition ratio close to a stoichiometric composition ratio of 1:1 in terms of an atom number ratio. By sufficiently nitriding the BN film in this way, it is possible to obtain a film in which the k value is 3.2 to 3.9, the leakage current at 2 MV is 2×10⁻⁹ A/cm² or less, and the surface roughness (Rms) as an index of the surface morphology is 0.2 to 0.5 nm.

Next, step S2 will be described in detail. At step S2, a diborane (B₂H₆) gas may be used as the boron-containing gas. An ammonia (NH₃) gas may be used as the nitriding gas. In addition, a boron trichloride (BCl₃) gas may be used as the boron-containing gas. Furthermore, an organic amine gas, hydrazine, N₂ plasma or NH₃ plasma may be used as the nitriding gas.

Moreover, an inert gas such as an N₂ gas, an Ar gas or the like may be used as a purge gas, a carrier gas or a dilution gas.

The expression “boron rich state due to an incomplete nitridation” used at step S2 refers to a state in which non-nitrided boron remains in a large amount. Hereinafter, the expression “the boron-rich nitride film which remains in a boron rich state due to an incomplete nitridation” sometimes is simply referred to as an “incompletely-nitrided and boron-rich nitride film.” The temperature for forming the B-rich BN film of this state may fall within a range of 250 to 400 degrees C., especially 280 to 380 degrees C.

The internal pressure of the process vessel at step S2 may fall within a range of 0.01 to 20 Torr (1.33 to 2.666 Pa). The flow rates of the boron-containing gas (B₂H₆ gas) and the nitriding gas (NH₃ gas) are not particularly limited and may be appropriately set depending on the apparatuses.

As described above, the B-rich BN film obtained at step S2 is an incompletely-nitrided film containing a large amount of boron. In general, if a large amount of B—N bonds exist in a film, the film becomes a nitrided film having a high insulation property. However, the B-rich BN film obtained at step S2 is a film having a low insulation property, in which B—B bonds are larger in amount than B—N bonds. From the viewpoint of improving the morphology, the boron content of the B-rich BN film may fall within a range of 50 to 90 at % (atoms %), especially a range of 60 to 80 at %. Furthermore, in the bonding state of B, it is more preferable that B—B bonds are larger in amount than B—N bonds. The amount of B—B bonds may be 30% or more. B—N bonds and B—B bonds can be measured by X-ray photoelectron spectroscopy (XPS analysis).

From the viewpoint of sufficiently nitriding the entirety of the B-rich BN film during the nitriding process of step S3, the thickness of the B-rich BN film formed at step S2 may be 2 nm or less.

Next, step S3 will be described in detail. The nitriding process of step S3 is a process in which a boron nitride film having a high insulation property is obtained by nitriding the B-rich BN film formed at step S2 and increasing the amount of nitrogen and B—N bonds in the film.

The nitriding process may be an annealing process in which a target substrate is heated while introducing a nitriding gas into the process vessel, or may be a plasma process which is performed using plasma of a nitriding gas.

In the case where the annealing process is performed without using plasma, an NH₃ gas may be used as the nitriding gas. In addition, an organic amine gas or a hydrazine gas may be used as the nitriding gas. From the viewpoint of sufficiently nitriding the B-rich BN film, the annealing process may be performed at a high temperature falling within a range of 550 to 900 degrees C., for example, at 700 degrees C. The annealing process may he performed using only the nitriding gas. Alternatively, the annealing process may be performed using an inert gas such as an N₂ gas, an Ar gas or the like together with the nitriding gas. The internal pressure of the process vessel during the annealing process may fall within a range of 0.01 to 150 Torr (1.33 to 19,995 Pa). A period of time during which the annealing process is performed, may fall within a range of 1 to 300 min.

In the case where the nitriding process is performed using a plasma process, plasma may be generated within the process vessel. Alternatively, remote plasma may be used. The method of generating plasma is not particularly limited but may be any method capable of forming a plasma gas which contains nitrogen radicals N*, ammonia radicals NH* or the like. In the case of the plasma process, it is not necessary to keep the substrate at a high temperature. The plasma process may be performed at the same temperature as used at step S2. An NH₃ gas or an N₂ gas may be used as the nitriding gas used in the plasma process. In addition, mixed plasma of H₂ and N₂ (plasma generated by simultaneously supplying an H₇, gas and an N₂ gas) may be used as the nitriding gas. In addition to the nitriding gas, an inert gas such as an Ar gas or the like may be added as a plasma generation gas. A period of time during which the plasma process is performed, may fall within a range of 1 to 600 sec.

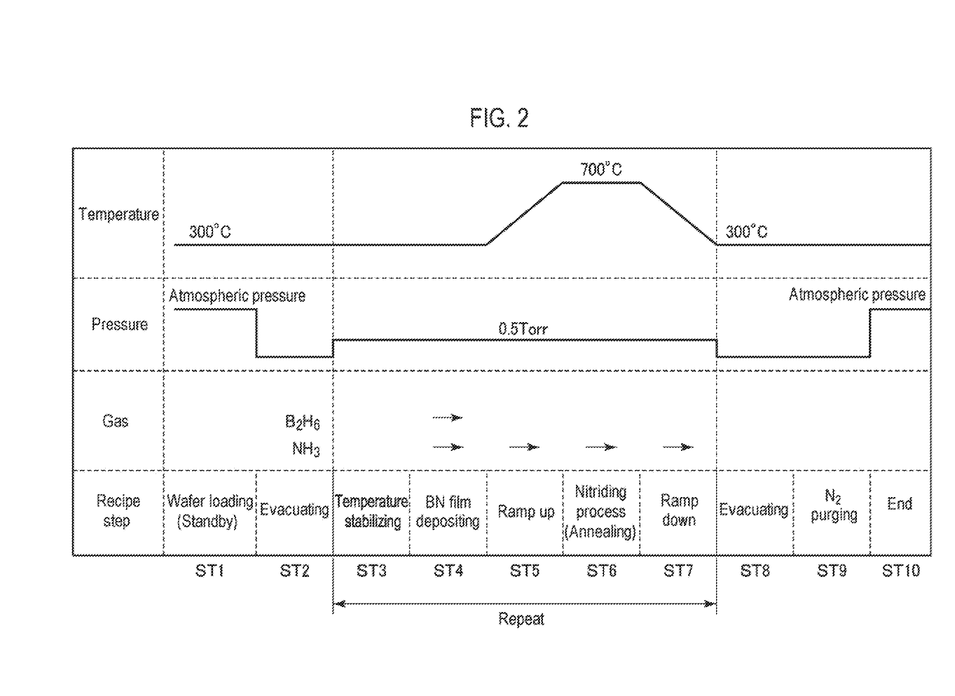

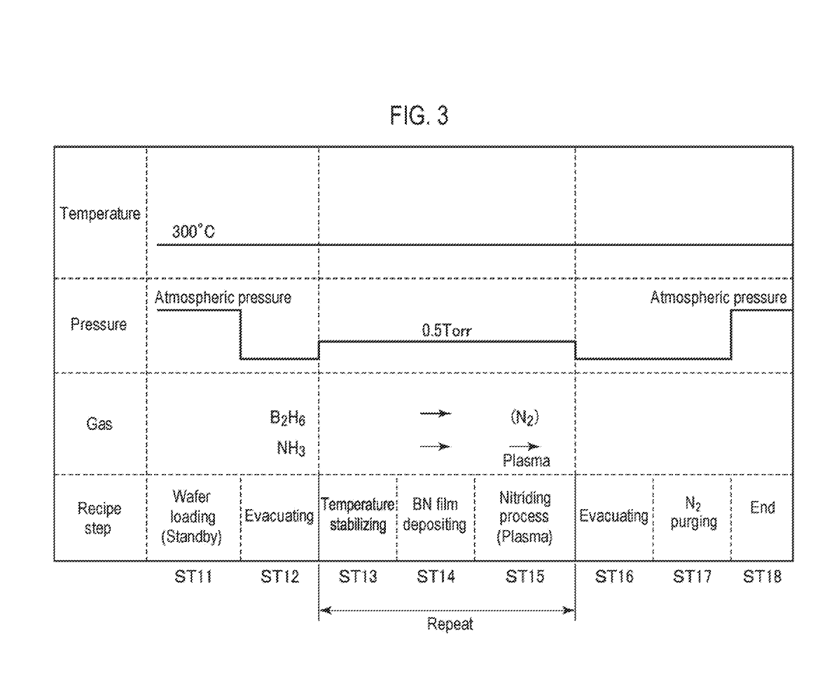

Next, descriptions will be made on a specific sequence. FIGS. 2 and 3 are timing charts illustrating specific sequence examples in which a boron nitride film is formed according to this embodiment. In FIGS. 2 and 3, there are shown a temperature, a pressure, an introduced gas and a recipe step. FIG. 2 illustrates a case where an annealing process is used as the nitriding process. FIG. 3 illustrates a case where a plasma process is used as the nitriding process.

In the example illustrated in FIG. 2, a wafer (silicon wafer), which is a target substrate, is loaded into the process vessel which is kept at 300 degrees C. and under atmospheric pressure, thereby bringing the process vessel into a standby state (ST1). In this state, evacuation is performed to bring the interior of the process vessel into a vacuum state (ST2). Then, the internal pressure of the process vessel is regulated to become 0.5 Torr (66.5 Pa) while maintaining the internal temperature of the process vessel at 300 degrees C., thereby stabilizing the temperature of the wafer (ST3). In this state, a B-rich BN film having a small thickness of 2 nm or less is deposited by CVD or ALD using a B₂H₆ gas as the boron-containing gas and using an ammonia (NH₃) gas as the nitrogen-containing gas (ST4). Subsequently, the internal temperature of the process vessel is ramped up to 700 degrees C. while stopping the supply of the B₇H₆ gas and supplying the NH₃ gas (ST5). A nitriding process is performed by annealing while maintaining the internal temperature of the process vessel at 700 degrees C. (ST6). Thus, boron contained in the B-rich BN film is nitrided, whereby the B-rich BN film becomes an additionally -nitrided BN film. After the nitriding process, the internal temperature of the process vessel is ramped down to 300 degrees C. (ST7). A BN film having a predetermined film thickness is obtained by repeating ST3 to ST7 a predetermined number of times. Thereafter, the interior of the process vessel is evacuated (ST8) and the interior of the process vessel is purged by an N₂ gas (ST9). Thereafter, the internal pressure of the process vessel is returned to an atmospheric pressure and the process is ended (ST10).

In the example illustrated in FIG. 3, a wafer loading step (ST11) and an evacuation step (ST12) similar to ST1 and ST2 of the example illustrated in FIG. 2 are performed. Thereafter, a temperature stabilization step (ST13) similar to ST3 is performed. Similar to ST4, a B-rich BN film is deposited by CVD or ALD (ST14). Subsequently, the temperature and the pressure are maintained at 300 degrees C. and 0.5 Torr (66.5 Pa), respectively. The supply of the B₂H₆ gas is stopped. A plasma-based nitriding process is performed by converting the NH₃ gas to plasma (ST15). At this time, an N₂ gas may be used as the nitriding gas. Thus, boron contained in the B-rich BN film is nitrided, whereby the B-rich BN film becomes an additionally-nitrided BN film. A BN film having a predetermined film thickness is obtained by repeating ST13 to ST15 a predetermined number of times. Thereafter, the interior of the process vessel is evacuated (ST16) and the interior of the process vessel is purged by an N₂ gas (ST17). Thereafter, the internal pressure of the process vessel is returned to an atmospheric pressure and the process is ended (ST18).

In the case where the nitriding process is performed using plasma as in FIG. 3, a plasma generation mechanism is needed and, therefore, an apparatus cost is increased. However, ramp-up and ramp-down are unnecessary. It is therefore possible to increase throughput.

The BN film formed according to this embodiment has good electrical properties (e.g., a k value and an insulation property). However, the BN film essentially has hygroscopicity. Thus, if the BN film is directly applied to an actual device, there is a possibility that the BN film absorbs moisture during the use of a device and the electrical properties of the BN film deteriorate. The deterioration of electrical properties attributable to the moisture absorption can be effectively prevented by using an insulation film, such as a SiN film or the like, capable of suppressing moisture absorption of the BN film, as a cap layer of the BN film.

### <Film Forming Apparatus>

Next, a film forming apparatus for implementing the boron nitride film forming method according to the aforementioned embodiment will be described.

### (First Example of Film Forming Apparatus)

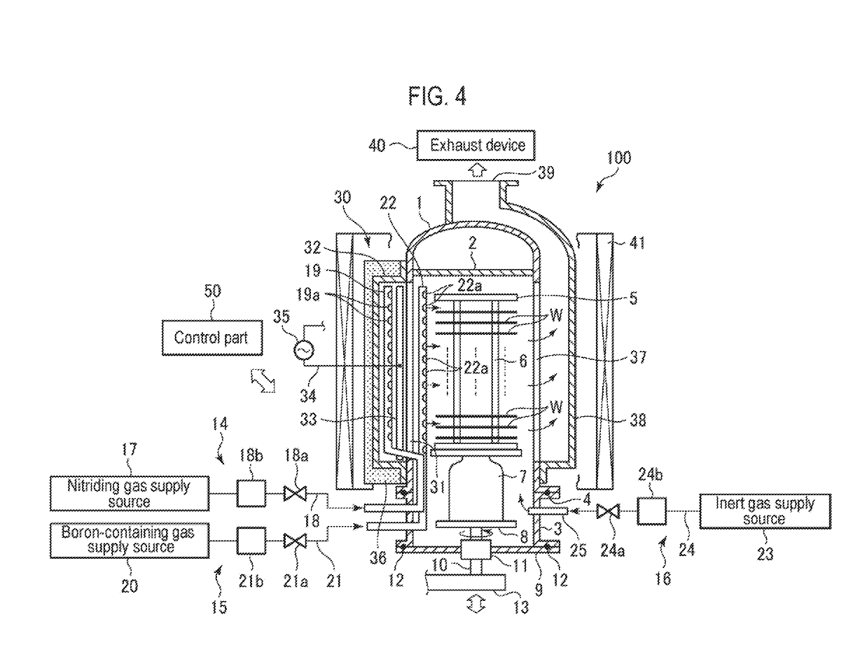

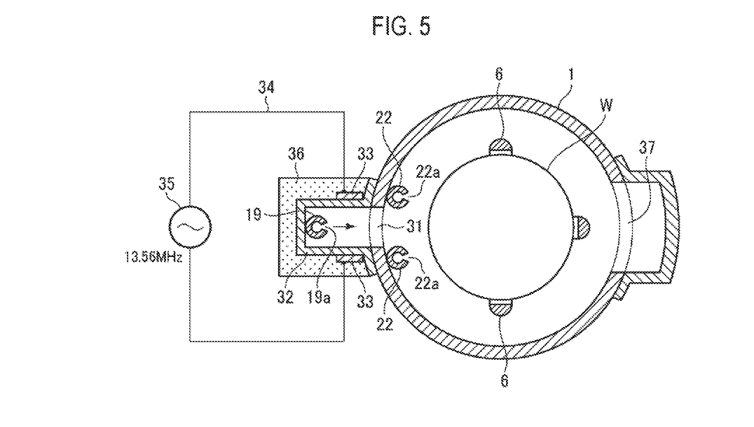

FIG. 4 is a vertical sectional view schematically illustrating a first example of a film forming apparatus for implementing the boron nitride film forming method according to one embodiment of the present disclosure. FIG. 5 is a horizontal sectional view of the film forming apparatus illustrated in FIG. 4.

A film forming apparatus 100 of this example includes a cylindrical process vessel 1 having an opened lower end and a ceiling. The entirety of the process vessel 1 is made of, for example, quartz. A quartz-made ceiling plate 2 is installed in the vicinity of an upper end portion within the process vessel 1. A region below the ceiling plate 2 is sealed. A manifold 3 formed in a cylindrical shape by, for example, stainless steel, is connected to a lower end opening portion of the process vessel 1 through a seal member 4 such as an O-ring or the like.

The manifold 3 is configured to support the lower end of the process vessel 1. A quartz-made wafer boat 5 capable of holding a plurality of, e.g., 50 to 100, semiconductor wafers (silicon wafers) W as target substrates in multiples stages, can be inserted into the process vessel 1 from the lower side of the manifold 3. The wafer boat 5 includes three rods 6 (see FIG. 5). The plurality of wafers W is supported by grooves (not shown) formed in each of the rods 6.

The wafer boat 5 is mounted on a table 8 through a quartz-made heat insulation cylinder 7. The table 8 is supported on a rotary shaft 10 extending through a lid 9 which is configured to open or close a lower end opening portion of the manifold 3. The lid 9 is made of, for example, stainless steel.

For example, a magnetic fluid seal 11 is installed in a portion of the lid 9 through which the rotary shaft 10 extends. The magnetic fluid seal 11 is configured to rotatably support the rotary shaft 10 while air-tightly sealing the rotary shaft 10. In addition, a seal member 12 for maintaining the sealability of the interior of the process vessel 1 is installed between a peripheral portion of the lid 9 and the lower end portion of the manifold 3.

The rotary shaft 10 is installed in a distal end of an arm 13 which is supported by an elevator mechanism (not shown) such as, for example, a boat elevator or the like. The wafer boat 5 and the lid 9 are integrally moved up and down and are inserted into or removed from the process vessel 1. In some embodiments, the table 8 may be fixedly installed in the lid 9 and the wafers W may be processed without rotating the wafer boat 5.

The film forming apparatus 100 further includes a nitriding gas supply mechanism 14 configured to supply a nitriding gas, for example, an NH₃ gas, into the process vessel 1, a boron-containing gas supply mechanism 15 configured to supply a boron-containing gas, for example, a B₂H₆ gas, into the process vessel 1, and an inert gas supply mechanism 16 configured to supply an inert gas as a purge gas, for example, an N₂ gas, into the process vessel 1.

The nitriding gas supply mechanism 14 includes a nitriding gas supply source 17, a gas pipe 18 configured to guide the nitriding gas supplied from the nitriding gas supply source 17, and a gas dispersion nozzle 19 connected to the gas pipe 18 and configured to guide the nitriding gas into the process vessel 1.

The boron-containing gas supply mechanism 15 includes a boron-containing gas supply source 20, a gas pipe 21 configured to guide the boron-containing gas supplied from the boron-containing gas supply source 20, and a gas dispersion nozzle 22 connected to the gas pipe 21 and configured to guide the boron-containing gas into the process vessel 1.

Each of the gas dispersion nozzles 19 and 22 is made of quartz. Each of the gas dispersion nozzles 19 and 22 penetrates the sidewall of the manifold 3, is bent upward and extends in a vertical direction in vertically-extended portions of the gas dispersion nozzles 19 and 22, a plurality of gas injection holes 19a and 22a is respectively formed in a spaced-apart relationship over a vertical length corresponding to a wafer support range in the wafer boat 5. A gas may be substantially uniformly injected from the gas injection holes 19a and 22a toward the process vessel 1 in a horizontal direction. While in this example, two gas dispersion nozzles 22 have been shown to be installed, a single gas dispersion nozzle 22 may be installed.

The inert gas supply mechanism 16 includes an inert gas supply source 23, a gas pipe 24 configured to guide the inert gas supplied from the inert gas supply source 23, and a gas nozzle 25 connected to the gas pipe 24 and formed of a short quartz pipe installed to penetrate the sidewall of the manifold 3. An N₂ gas, an Ar gas or the like may be used as the inert gas.

Opening/closing valves 18a, 21a and 24a and flow rate controllers 18b, 21b and 24b are installed in the gas pipes 18, 21 and 24, respectively.

A plasma generation mechanism 30 is installed in a portion of the sidewall of the process vessel 1. The plasma generation mechanism 30 is to apply energy so that the nitriding gas is excited and converted to plasma. The plasma generation mechanism 30 includes a plasma partition wall 32 air-tightly welded to the outer wall of the process vessel 1. The plasma partition wall 32 is made of, for example, quartz. The plasma partition wall 32 has a recessed cross-sectional shape and covers an opening 31 formed in the sidewall of the process vessel 1. The opening 31 is formed in a vertically elongated shape by, for example, cutting away the sidewall of the process vessel 1, so that the opening 31 vertically covers all the semiconductor wafers NV supported on the wafer boat 5. The gas dispersion nozzle 19 configured to inject the nitriding gas is disposed within an internal space, namely a plasma generation space, which is defined by the plasma partition wall 32.

The plasma generation mechanism 30 further includes a pair of elongated plasma electrodes 33 disposed on outer surfaces of the opposite sidewalls of the plasma partition wall 32 so as to face each other along a vertical direction, and a high-frequency power source 35 connected to the plasma electrodes 33 via respective power supply lines 34 and configured to supply high-frequency power to the plasma electrodes 33. The high-frequency power source 35 is configured to apply a high-frequency voltage of, for example, 13.56 MHz, to the plasma electrodes 33. Thus, a high-frequency electric field is generated within the plasma generation space defined by the plasma partition wall 32. The nitriding gas injected from the gas dispersion nozzle 19 is converted to plasma within the plasma generation space in which the frequency electric field is generated. Thus, a plasma gas containing, for example, nitrogen radicals N* or ammonia radicals NH*, is supplied into the process vessel 1 through the opening 31. In the film forming apparatus 100, by stopping the supply of the high-frequency power to the plasma electrodes 33, the nitriding gas injected from the gas dispersion nozzle 19 may be supplied into the process vessel 1 without converting the nitriding gas to plasma, in the case of converting the nitriding gas to plasma, an N₂ gas may be used as the nitriding gas.

An insulating protection cover 36 made of, for example, quartz, is installed outside of the outer side of the plasma partition wall 32 to cover the plasma partition wall 32. A coolant path (not shown) is formed in an inner portion of the insulating protection cover 36. A coolant, for example, a cooled nitrogen gas, flows through the coolant path, thus cooling the plasma electrodes 33.

The two gas dispersion nozzles 22 are installed in the inner wall of the process vessel 1 so as to interpose the opening 31 therebetween. The boron-containing gas can be injected from the gas injection holes 22a of the gas dispersion nozzles 22 toward the center of the process vessel 1.

An exhaust port 37 through which the interior of the process vessel 1 is vacuum-exhausted, is formed in a portion facing the gas dispersion nozzles 19 and 22 in the sidewall of the process vessel 1. The exhaust port 37 is formed in an elongated shape by vertically cutting away the sidewall of the process vessel 1. In a portion of the process vessel 1 corresponding to the exhaust port 37, an exhaust port cover member 38 having a U-like cross-sectional shape is installed by welding so as to cover the exhaust port 37. The exhaust port cover member 38 extends upward along the sidewall of the process vessel 1 and defines a gas outlet 39 at the upper side of the process vessel 1. The interior of the process vessel 1 is evacuated from the gas outlet 39 by an exhaust device 40 including a vacuum pump or the like. In addition, a cylindrical heating mechanism 1 configured to heat the process vessel 1 and the wafers W existing within the process vessel 1 is installed so as to surround the outer periphery of the process vessel 1.

The film forming apparatus 100 includes a control part 50. The control part 50 executes control of respective components of the film forming apparatus 100, for example, control of the supply and cutoff of the respective gases performed by the opening/closing of the valves 18a, 21a and 24a, control of the gas flow rate using the flow rate controllers 18b, 21b and 24b, exhaust control using the exhaust device 40, on/off control of the high-frequency power using the high-frequency power source 35, control of the temperature of the wafers W using the heating mechanism 41, and the like. The control part 50 includes: a controller equipped with a microprocessor (computer); a user interface including a keyboard through which an operator performs a command input operation or the like in order to manage the film forming apparatus 100 and a display which visually displays an operation situation of the film forming apparatus 100; and a memory part which stores a control program for realizing various kinds of processes performed in the film forming apparatus 100 under the control of the controller, and a program (i.e., a process recipe) for causing the respective components of the film forming apparatus 100 to perform a process according to a process condition. If necessary, the control part 50 calls out an arbitrary recipe from the memory part in response to an instruction received from the user interface and causes the controller to execute the arbitrary recipe. Thus, a desired process is performed in the film forming apparatus 100 under the control of the controller.

In the film forming apparatus 100 configured as above, the boron nitride film forming method according to the aforementioned embodiment is realized under the control of the control part 50. Specifically, the wafer boat 5 configured to hold, for example, 50 to 100 wafers W, is loaded into the process vessel 1 while maintaining the interior of the process vessel 1 at, for example, 300 degrees C. The interior of the process vessel 1 is evacuated. Subsequently, the internal pressure of the process vessel 1 is regulated to, for example, 0.5 Torr (66.5 Pa).

Subsequently, the plasma generation mechanism 30 is turned off. In this state, a thin B-rich BN film is deposited by CVD in which a B₂H₆ gas as the boron-containing gas and an NH₃ gas as the nitriding gas are simultaneously supplied from the boron-containing gas supply mechanism 15 and the nitriding gas supply mechanism 14 into the process vessel 1 or by ALD in which the B₂H₆ gas and the NH₃ gas are alternately supplied while purging the interior of the process vessel 1 using an inert gas between the supply of the B₂H₆ gas and the supply of the NH₃ gas.

Thereafter, the supply of the B₂H₆ gas as the boron-containing gas is stopped and the NH₃ gas as the nitriding gas is continuously supplied. In this state, the plasma generation mechanism 30 is turned on, whereby a nitriding process using the plasma of the NH₃ gas as the nitriding gas is performed with respect to the B-rich BN film. The plasma may be generated by using an N₂ gas as the nitriding gas. By performing the aforementioned processes once or by repeating the aforementioned processes multiple times, a BN film laving a predetermined film thickness is obtained.

### (Second Example of Film Forming Apparatus)

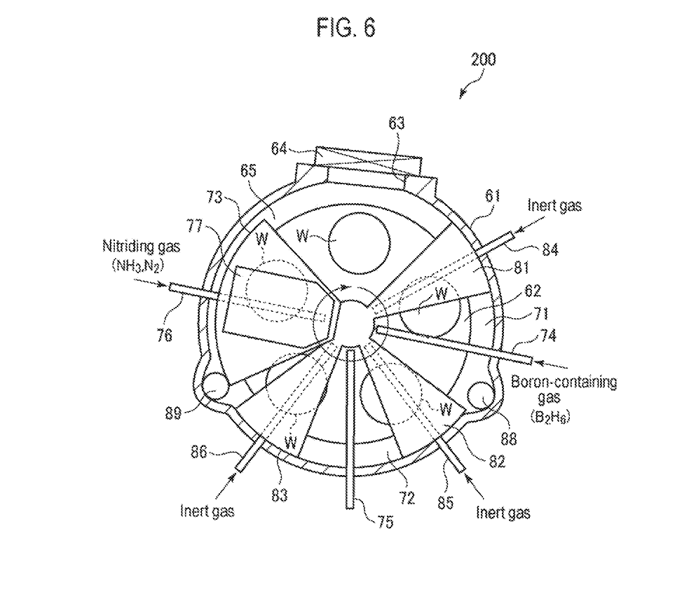

FIG. 6 is a horizontal sectional view schematically illustrating a second example of a film forming apparatus for implementing the boron nitride film forming method according to one embodiment of the present disclosure.

A film forming apparatus 200 of this example includes a cylindrical process vessel 61. A turntable 62 configured to mount thereon a plurality of, for example, 5 wafers, is installed within the process vessel 61. The turntable 62 is rotated, for example, clockwise.

A loading/unloading gate 63 through which the wafers W is loaded and unloaded, is formed in a peripheral wall of the process vessel 61. The loading/unloading gate 63 is opened and closed by a gate valve 64. A region corresponding to the loading/unloading gate 63 within the process vessel 61 is defined as a loading/unloading portion 65. In the loading/unloading portion 65, the loading of the wafers W onto the turntable 62 and the unloading of the wafers W from the turntable 62 are performed.

The interior of the process vessel 61 is divided into six areas along a rotation region of the turntable 62 except for the loading/unloading portion 65. Specifically, the interior of the process vessel 61 is divided into a first process area 71, a second process area 72 and a third, process area 73, which are disposed clockwise from the side of the loading/unloading portion 65. Furthermore, the interior of the process vessel 61 is divided into a first separation area 81 disposed between the loading/unloading portion 65 and the first process area 71, a second separation area 82 disposed between the first process area 71 and the second process area 72, and a third separation area 83 disposed between the second process area 72 and the third process area 73. By rotating the turntable 62, the wafers W sequentially pass through the six areas. The first to third separation areas 81 to 83 serve to separate gas atmospheres of the first to third process areas 71 to 73.

In the first process area 71, the second process area 72 and the third process area 73, a first process gas nozzle 74, a second process gas nozzle 75 and a third process gas nozzle 76, which are configured to inject process gases toward the wafers W mounted on the turntable 62, are radially installed along the radial direction of the process vessel 61. A plasma generation mechanism 77 for converting the process gas injected from the third process gas nozzle 76 to plasma is installed in the third process area 73.

In the first separation area 81, the second separation area 82 and the third separation area 83, a first inert gas nozzle 84, a second inert gas nozzle 85 and a third inert gas nozzle 86, which are configured to inject an inert gas toward the wafers W mounted on the turntable 62, are radially installed along the radial direction of the process vessel 61. As the inert gas is injected from the nozzles 84, 85 and 86, the gas atmospheres are separated from each other.

Two exhaust ports 88 and 89 are formed in the bottom portion of the process vessel 61. The interior of the process vessel 61 is exhausted through the exhaust ports 88 and 89.

In FIG. 6, a process gas supply mechanism, an inert gas supply mechanism, an exhaust device and a control part are omitted. In this example, a heating device is installed within the turntable 62

When the boron nitride film forming method of the aforementioned embodiment is implemented by the film forming apparatus 200 illustrated in FIG. 6, a boron-containing gas, for example, a B₂H₆ gas, is supplied from the first process gas nozzle 74. A nitriding gas, for example, an NH₃ gas, is supplied from the third process gas nozzle 76. The second process gas nozzle 75 is not used. Thus, the first process area 71 is defined as a boron-containing gas supply area. The third process area 73 is defined as a nitriding gas supply area. The second process area 72 is defined as a wafer passing area.

In the film forming apparatus 200 configured as above, the boron nitride film forming method of the aforementioned embodiment is realized by the control of the control part (not shown). Specifically, the turntable 62 is first heated. In this state, a plurality of, for example, 5, wafers W, are sequentially mounted on the turntable 62. The internal pressure of the process vessel 61 is regulated to, for example, 0.5 Torr (66.5 Pa). The temperature of the wafers W is controlled to be kept at 300 degrees C.

Subsequently, the plasma generation mechanism 77 is turned off. In this state, the B₂H₆ gas as the boron-containing gas is injected from the first process gas nozzle 74. The NH₃ gas as the nitriding gas is injected from the third process gas nozzle 76. The inert gas (an N₂ gas, an Ar gas, etc.) is injected from the first to third inert gas nozzles 84 to 86. In this state, the turntable 62 is rotated. Thus, the B₂H₆ gas, the inert gas, the NH₃ gas and the inert gas are sequentially supplied to the wafers W. A B-rich BN film is deposited by ALD. At this time, one rotation of the turntable 62 corresponds to one cycle of ALD. By rotating the turntable 62 a predetermined number of times, it is possible to deposit a B-rich BN film having a predetermined film thickness.

Thereafter, the supply of the B₂H₆ gas is stopped and the NH₃ gas as the nitriding gas is continuously supplied to the third process area 73. In this state, the plasma generation mechanism 77 is turned on. While rotating the turntable 62, a nitriding process using the plasma of the NH₃ gas is sequentially performed with respect to the B-rich BN films of the wafers W mounted on the turntable 62. The plasma may be generated by using an N₂ gas as the nitriding gas.

A BN film having a predetermined film thickness is obtained by performing the deposition of the B-rich BN film and the nitriding process once or by repeating the deposition of the B-rich BN film d the nitriding process multiple times.

In the first and second examples of the aforementioned film forming apparatus, there is illustrated an example in which the plasma generation mechanism for converting the nitriding gas to plasma is used. However, the nitriding process may be performed by annealing at an elevated temperature without using the plasma generation mechanism.

### EXPERIMENTAL EXAMPLES

Next, descriptions will be made on experimental examples.

### Experimental Example 1

In this experimental example, in order to investigate the influence of the film forming temperature and the annealing, there were prepared samples (samples 1 and 2) formed by CVD at 550 degrees C. and 300 degrees C. using a B₂H₆ gas and an NH₃ gas, and samples (samples 3 and 4) obtained by annealing (nitriding annealing) samples 1 and 2 at 700 degrees C. using an NH₃ gas as a nitriding gas.

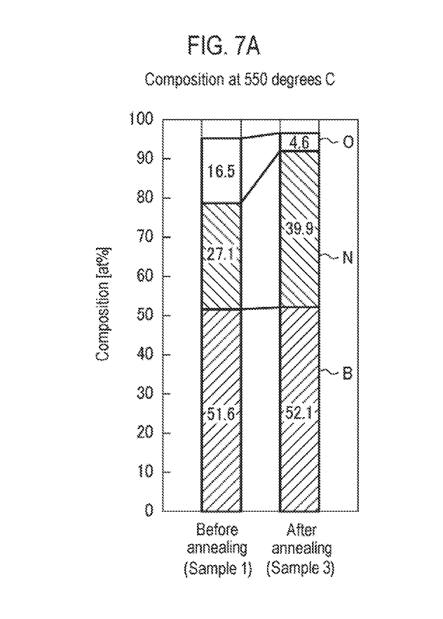

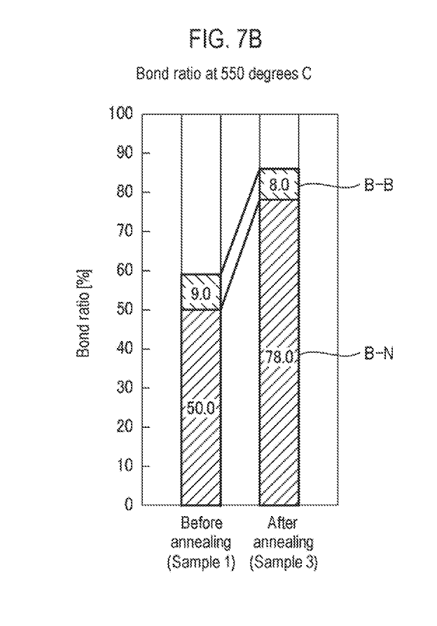

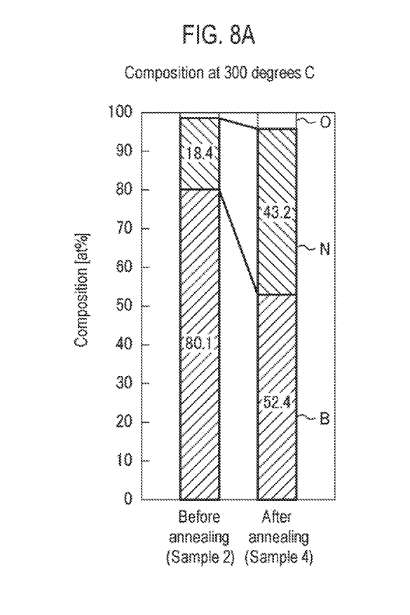

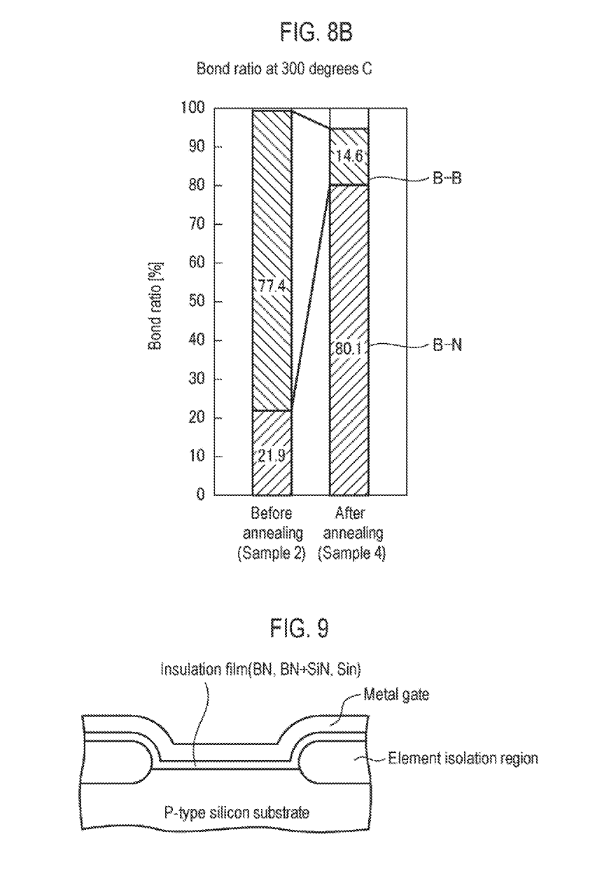

Compositions and bond ratios of the samples were measured by XPS analysis. FIGS. 7A and 7B illustrate compositions and bond ratios of the samples (samples 1 and 3) before and after the nitriding annealing when a film formation process is performed at 550 degrees C. FIGS. 8A and 8B illustrate compositions and bond ratios of the samples (samples 2 and 4) before and after the annealing when a film formation process is performed at 300 degrees C.

As illustrated in FIGS. 7A, 7B, 8A and 8B, it can be noted that the sample (sample 2) formed at 300 degrees C. is much higher in B content rate and B—B bond ratio than the sample (sample 1) formed at 550 degrees C. so that the incompletely-nitrided and boron-rich nitride film is formed. In contrast, it can be noted that, in the samples (samples 3 and 4) subjected to the nitriding annealing, the B/N ratios and the B—N bond ratios remain the same, and the B/N ratios are close to a stoichiometric composition, thus obtaining well-nitrided BN films having a high B—N bond ratio. It was confirmed from the above results that the incompletely-nitrided and boron-rich nitride film obtained by the low-temperature film formation process is modified to a well-nitrided nitride film by the nitriding annealing.

Then, the surface morphology and the density were measured with respect to samples 1 to 4. As a result, sample 1 formed at 550 degrees C. has a large surface roughness (Rms) of 2.34 nm, a low density of 0.9 g/cm³ and a poor surface morphology. Thus, sample 1 is a crumbly film. Sample 3 obtained by performing the nitriding annealing with respect to sample 1 has a surface roughness (Rms) of 2.56 nm and a density of 1.05 g/cm³, which remain the same as those available before annealing. In contrast, sample 2 formed at 300 degrees C. has a surface roughness (Rms) of 0.26 nm, a good surface morphology and a relatively high density of 1.69 g/cm³. Sample 4 obtained by subjecting sample 2 to the nitriding annealing has a surface roughness (Rms) of 0.64 nm and a density of 1.93 g/cm³. Thus, it was confirmed that, even when the nitriding annealing is performed, the surface morphology is kept good and the density is increased.

### Experimental Example 2

In this experimental example, as illustrated in FIG. 9, an element isolation region was formed on a major surface of a p-type silicon substrate. After wet cleaning is performed, an insulation film was formed on the major surface of the p-type silicon substrate. Furthermore, a metal gate was formed on the insulation film. Thereafter, MOS-type TEG samples were prepared by sintering (annealing). Tests of electrical properties thereof were conducted.

As the TEG samples, three kinds of samples, namely a sample (BN (20 nm); sample 5) in which a BN film having a film thickness of 20 nm is formed as an insulation film by the aforementioned embodiment, a sample (SiN (10 nm)/BN (20 nm); sample 6) in which a SiN film having a film thickness of 10 nm is formed as a cap layer on the BN film, and a sample (SiN (20 nm); sample 7) in which a SiN film having a film thickness of 20 nm is formed.

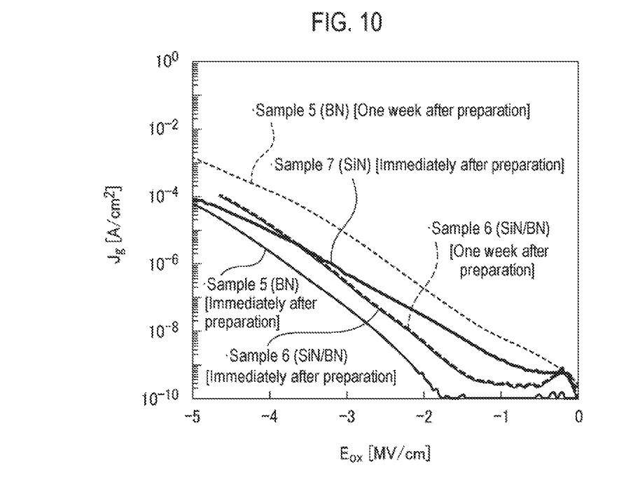

With respect to these TEG samples, a leakage current available when an electric field strength is changed immediately after preparation of the TEG samples was measured. With respect to samples 5 and 6, a leakage current available when an electric field strength is changed one week after preparation of the TEG samples was also measured. The relationship between the electric field strength and the leakage current available at that time is illustrated in FIG. 10.

As illustrated in FIG. 10, sample 5 using only the BN film as the insulation film is better in the leakage current property measured immediately after preparation than the sample (sample 7) using the SiN film as the insulation film. However, the leakage current property measured one week after preparation was reduced. This is because the BN film essentially has hygroscopicity. In contrast, sample 6 in which the SiN film is formed as the cap layer on the BN film shows a good leakage current property either immediately after preparation or one week after preparation. Thus, it was confirmed that, by capping the BN film with the SiN film, it is possible to prevent changes over time in the leakage current.

Next, a first TEG sample group in which BN films having different film thicknesses formed by the method of the aforementioned embodiment are used as insulation films and a second TEG sample group in which laminated films obtained by forming SiN films having a film thickness of 10 nm as cap layers on BN films having different film thicknesses formed by the aforementioned embodiment are used as insulation films, were prepared. With respect to the first and second TEG sample groups, a C—V measurement was performed immediately after preparation and for one week after preparation. A film thickness (EOT) of the insulation film in terms of SiO₂ was calculated from the C—V measurement result. A K value of the BN film was calculated from the relationship between the film thickness of the BN film measured by a transmission electron microscope (TEM) and the EOT As a result, in the BN film not provided with a cap layer, the k value measured immediately after preparation was 3.5. The k value was increased to 3.9 after one week elapsed. However, the k value was still 4 or less. In the case where the SiN film is formed as a cap layer on the BN film, the k value of the BN film measured immediately after preparation was 3.2, which is lower than the k value available when the BN film is used alone. Even after one week elapses, the k value of the BN film was 3.4. Thus, the over-time change of the k value was small. It was confirmed from the above result that the k value is further educed by capping the SiN film on the BN film formed by the method according to this embodiment.

### <Other Application>

For example, the sequence example of the aforementioned embodiment is nothing more than one example and may be appropriately changed depending on the apparatus used. Furthermore, the film forming apparatus is not limited to the illustrated one. Other different film forming apparatuses such as a horizontal batch-type apparatus, a single-substrate-type apparatus and the like may be used. In addition, while the SiN film has been illustrated as the cap layer, the cap layer is not limited to the SiN film. Other insulation films, such as an SiCN film, an SiC film and the like, which are capable of suppressing moisture absorption of the BN film, may be used as the cap layer.

According to the present disclosure in some embodiments, it is possible to obtain a boron nitride film capable of achieving both good electrical properties and a good surface morphology.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A boron nitride film forming method for forming a boron nitride film on a target substrate, comprising:
a first operation of introducing a boron-containing gas and a nitriding gas into a process vessel which accommodates the substrate, and depositing an incompletely-nitrided and boron-rich nitride film on the substrate by CVD or ALD; and
a second operation of introducing a nitriding gas into the process vessel and subjecting the boron-rich nitride film to a nitriding process,
wherein the first operation and the second operation are performed at least one.

2. A boron nitride film forming method for forming a boron nitride film on a target substrate, comprising:
a first operation of introducing a boron-containing gas and a nitriding gas into a process vessel which accommodates the substrate, while keeping a temperature of the substrate at 250 to 400 degrees C., and depositing a boron-rich nitride film on the substrate by CVD or ALD; and
a second operation of introducing a nitriding gas into the process vessel and subjecting the boron-rich nitride film to a nitriding process,
wherein the first operation and the second operation are performed at least one.

3. The method of claim 1, wherein the boron-rich nitride film has a boron content which falls within a range of 50 to 90% in terms of atoms %.

4. The method of claim 1, wherein the boron-rich nitride film has 30% or more of B—B bonds in a bonding state of boron.

5. The method of claim 1, wherein at the first operation, a diborane (B₂H₆) gas is used as the boron-containing gas and an ammonia (NH₃) gas is used as the nitriding gas.

6. The method of claim 1, wherein the boron-rich nitride film formed at the first operation has a film thickness of 2 nm or less.

7. The method of claim 1, wherein the second operation is performed by an annealing process of heating the substrate while introducing the nitriding gas into the process vessel.

8. The method of claim 7, wherein the second operation is performed by using an ammonia (NH₃) gas as the nitriding gas.

9. The method of claim 1, wherein the second operation is performed by a plasma process using plasma of the nitriding gas.

10. The method of claim 9, wherein the second operation is performed by using an ammonia (NH₃) gas or a nitrogen gas as the nitriding gas.

11. The method of claim 9, wherein the second operation is performed at the same temperature as that used at the first operation.

12. A semiconductor device manufacturing method, comprising:
forming a boron nitride film on a substrate by the method of claim 1; and
forming an insulation film as a cap layer which suppresses moisture absorption of the boron nitride film on the boron nitride film.

13. The method of claim 12, wherein the cap layer is a SiN film.

14. A semiconductor device manufacturing method, comprising:
forming a boron nitride film on a substrate by the method of claim 2; and
forming an insulation film as a cap layer which suppresses moisture absorption of the boron nitride film on the boron nitride film.

15. The method of claim 14, wherein the cap layer is a SiN film.
